(19) United States
(12) Patent Application Publication
(10) Pub. No.: US 2017/0180026 A1
(43) Pub. Date: Jun. 22, 2017

(54) NARROWBAND BITSTREAM BEAM-FORMER WITH AN INTEGRATED ARRAY OF CONTINUOUS-TIME BANDPASS SIGMA-DELTA MODULATORS

(71) Applicant: THE REGENTS OF THE UNIVERSITY OF MICHIGAN, Ann Arbor, MI (US)

(72) Inventors: Michael FLYNN, Ann Arbor, MI (US); Jaehun JEONG, Ann Arbor, MI (US); Nicholas COLLINS, Ann Arbor, MI (US)

(21) Appl. No.: 15/300,556

(22) PCT Filed: Mar. 31, 2015
(86) PCT No.: PCT/US2015/023556

§ 371 Date: Sep. 29, 2016

Related U.S. Application Data
(60) Provisional application No. 61/972,678, filed on Mar. 31, 2014.

(51) Int. Cl. H04B 7/06; H03M 3/00

(52) U.S. Cl. CPC H04B 7/0617; H03M 3/458

(57) ABSTRACT

A new power and area efficient ADC-digital co-design approach is introduced to IF digital beam forming that combines continuous-time band-pass ΔΣ modulators and bit-stream processing. An array of compact (0.03 mm2), low-power (13.1 mW) delta sigma modulators directly digitizes 260 MHz IF signals from eight input elements. Digital beam forming is directly performed on the over-sampled, undecimated low-resolution outputs of the delta sigma modulator array. The unique combination of delta sigma modulators and bit stream processing has several advantages.

### CROSS-REFERENCE TO RELATED APPLICATIONS

This application claims the benefit of U.S. Provisional Application No. 61/972,678, filed on Mar. 31, 2014. The entire disclosure of the above application is incorporated herein by reference.

### GOVERNMENT CLAUSE

This invention was made with government support under N66001-14-1-4014 awarded by the U.S. Navy/SPAWAR. The Government has certain rights in the invention.

### FIELD

The present disclosure relates to a narrowband bit-stream beam-former with an integrated array of bandpass sigma-delta modulators.

### BACKGROUND

Beamforming improves SNR, and enables spatial filtering of interferers in receivers. However, high power consumption, large area, and routing complexity are bottlenecks to implementing an efficient beamforming system, especially for large numbers of elements. Conventionally, beamforming is implemented in the analog/RF domain in integrated circuits. With RF beamforming, since signals are combined in the RF domain, the intermediate frequency (IF) and baseband hardware, including mixers and ADCs, can be minimized. However, RF beamforming is limited by high insertion loss, component mismatch, and low SNR.

Digital beamforming (DBF) offers the highest accuracy and flexibility. Another significant advantage is that DBF can simultaneously form multiple beams. However, despite these advantages, the adoption of DBF has been limited by high power consumption and large die area due to the need for multiple high-performance ADCs and extensive DSP. For these reasons, DBF is largely confined to base station applications, and implemented with FPGAs or in software. IF DBF is even more compelling because it simplifies the receiver chain by moving the ADCs closer to the antennas, and allowing I/Q down-conversion to be accurately implemented in the digital domain. However, power consumption and die area of convention high-speed ADCs are prohibitive.

This section provides background information related to the present disclosure which is not necessarily prior art.

### SUMMARY

This section provides a general summary of the disclosure, and is not a comprehensive disclosure of its full scope or all of its features.

A method is provided for digital beamforming. The method includes: receiving, by an array of sigma delta modulators, a plurality of analog radio frequency (RF) signals from an RF front-end; converting, by the array of sigma delta modulators, each of the analog RF signals into a corresponding digital signal using sigma-delta modulation; bit-stream processing, by a bit stream processor, the digital signals received directly from the array of sigma delta modulators, where the bit-stream processing includes down mixing each digital signal using a first multiplication operation and phase shifting each multiplied digital signal by weighting the respective multiplied digital signal using a second multiplication operation; and summing, by the bit stream processor, each of the bit-stream processed digital signals to a form a resultant signal. The resultant signal may in turn be decimated using a filter.

In one embodiment, each digital signal is down mixed at one quarter sampling rate of the sigma delta modulators.

In some embodiments, the method is further defined another as follows: receiving, by an array of sigma delta modulators, a plurality of intermediate frequency (IF) analog signals from an RF front-end; converting, by the array of sigma delta modulators, each of the IF analog signals into a corresponding digital signal using sigma-delta modulation; down mixing, by a first set of multiplexers, each digital signal by multiplying the respective digital signal by a multiplier, where the multiplier is selected from a group of one, zero or minus one; weighting, by a second set of multiplexers, each down mixed digital signal with a weight, where the weight is selected from a group of two, one, zero, minus one or minus two; and summing, by the bit stream processor, each of the weighted digital signals together to form a resultant digital signal.

Each digital signal may be down mixed to generate a corresponding in-phase signal and a corresponding quadrature signal. After weighting of each signal, one of the weighted in-phase signal and the weighted quadrature signal are summed together. Since one of these is always zero this can be done by selection, for example using a 2:1 multiplexer.

In another aspect, a digital beamformer is provided. The digital beamformer includes: an array of sigma delta modulators, each sigma delta modulator configured to receive an intermediate frequency (IF) analog signal and operates to convert the IF analog signal to a corresponding digital signal; a first set of multiplexers configured to receive the digital signals from the array of sigma delta modulators, each multiplexer in the first set of multiplexers operates to down mix one of the digital signals using a multiplication operation; a second set of multiplexers configured to receive the down mixed digital signals from the first set of multiplexers and operates to phase shift each down mixed digital signal using a multiplication operations; and a set of additive mixers configured to receive the phase shifted digital signals from the second set of multiplexers and operates to add the phase shifted signals together to form a resultant digital signal. The digital beamformer may further include one or more decimator filters, where the number of decimator filters equals the number of resultant signals.

In some embodiments, each sigma delta modulator in the array of sigma delta modulators is further defined as a continuous-time band-pass sigma delta modulator.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a diagram depicting an example an 8-element 2-beam digital beamformer;

FIG. 2 is a schematic of an example circuit implementation of the 4^{th} order continuous-time band-pass sigma delta modulator;

FIG. 3A is a diagram illustrating the mathematical operations of digital down-conversion and phase shifting;

FIG. 3B is a diagram of an example implementation of MUX-based digital down-conversion;

FIG. 4A is a diagram illustrating digital down-conversion implemented with a 3:1 multiplexer;

FIG. 4B is a diagram illustrating complex weight multiplication with a 5:1 multiplexer;

FIG. 5 is a diagram further illustrating a partial example implementation of bit-stream processing in the context of the proposed digital beamformer;

FIG. 6A is a diagram illustrating an example digital signal processing implementation of an 8-element beamformer;

FIG. 6B is a diagram illustrating an example bit stream processing implementation of an 8-element beamformer;

FIGS. 7A and 7B are graphs comparing power and area comparison, respectively, for the proposed bit-stream processing and convention digital signal processing;

FIG. 8A is a plot of the measured spectrum of the single CTBPDSM output;

FIG. 8B is a plot of the measured spectrum of the beam output;

FIGS. 9A-9D are plots of measured and ideal beam patterns (with one main-lobe) steered at 0, 30, 45 and 60 degrees, respectively; and

FIGS. 10A-10D are plots of measured and ideal beam patterns (with two main-lobes) steered at 0, 30, 45 and 60 degrees, respectively.

Corresponding reference numerals indicate corresponding parts throughout the several views of the drawings.

### DETAILED DESCRIPTION

Example embodiments will now be described more fully with reference to the accompanying drawings.

FIG. 1 is a diagram of an example digital beamformer 10. In this example, eight input signals are formed into two output signals although more or less inputs and/or outputs are contemplated by this disclosure. The beamformer 10 is comprised generally of an analog-to-digital converter section 2, a digital down mixing section 4, a phase shifter section 6 and a decimation filter 8. Each of these sections is further described below.

In an example embodiment, the ADC section 2 includes an array of sigma delta modulators, where each sigma delta modulator 12 may be implemented as a continuous-time band-pass sigma delta modulator. Each sigma delta modulator is configured to receive an intermediate frequency (IF) analog signal from an RF front-end and operates to convert the IF analog signal to a corresponding digital signal. The stream of narrow digital word outputs of the sigma delta modulators are referred to herein as a bit-stream. For example, the array of sigma delta modulators digitizes 260 MHz IF signals from eight input elements at 1040 MS/s over a 20 MHz bandwidth and outputs a five-level digital output. In other embodiments, the array of sigma delta modulators may be configured to receive RF signals directly from antennas or an RF front-end.

Digital signals then undergo bit-stream processing by a bit stream processor comprised of the digital down mixing section 4 and the phase shifter section 6. Each digital signal is down mixed using a first multiplication operation and then phase shifted using another multiplication operation. In one example, the signals are phase-shifted by multiplication with programmable 6b complex weights. In this approach, the 5-level digitized signals are directly processed without decimation filtering for I/Q digital down-conversion and phase shifting. This novel bit-stream processing approach replaces bulky digital multipliers with simple multiplexers (MUXes), greatly reducing circuit complexity. Phase-shifted signals are summed by a summer 18 to create 1040 MS/s 10b beam outputs. The beam outputs are in turn passed through a decimation filter 19. In this example, the beam outputs are low-pass filtered and decimated by four to produce the overall 260 MS/s 13b I/Q outputs. It is noted that the number of decimator filters is equal to the number of resultant beam signals.

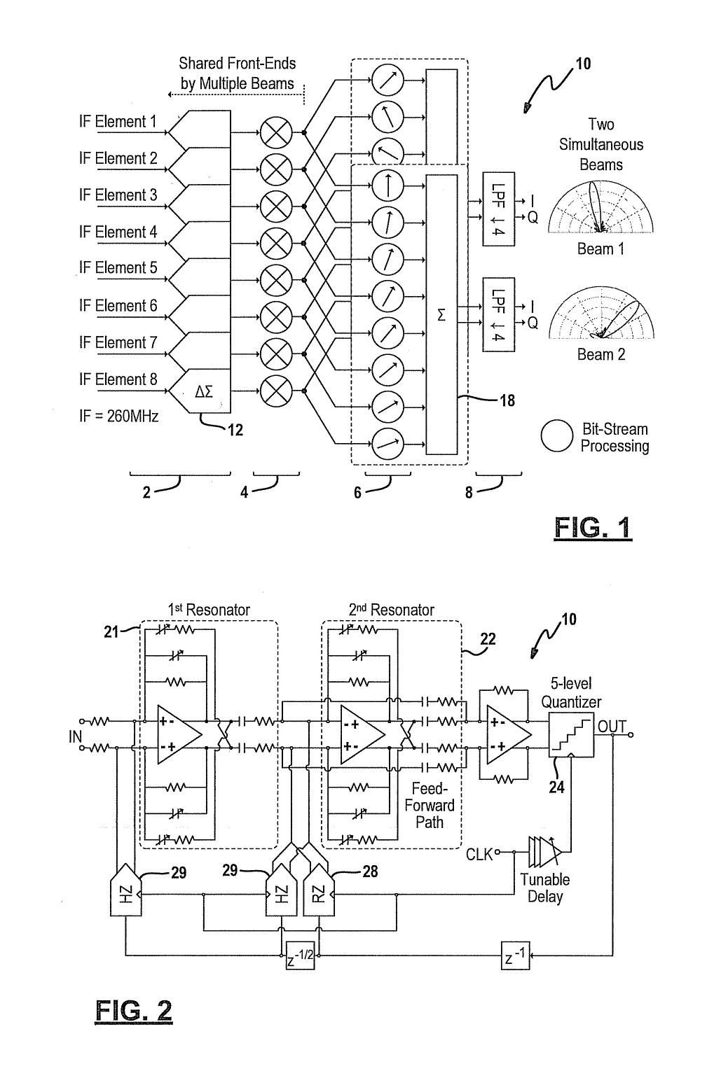

An example circuit implementation of a 4^{th} order continuous-time band-pass delta-sigma modulators (CTBPDSMs) is shown in FIG. 2. Since an N-element digital beamformer requires N ADCs, the power consumption and area of ADCs play a large role in the power consumption and area of the entire beamformer 10. In the modulator, single op-amp resonators consume less power, and are smaller than conventional LC-tank resonators. A high quality factor first resonator 21 is realized with a single op-amp by using positive feedback.

In one example, the resonator center frequency of fₛ/4 (260 MHz) simplifies the design of digital direct down-conversion. In direct down conversion, the mixer multiplies the IF or RF signal by a sine wave with a frequency the same as the carrier frequency. If the carrier frequency is ¼ of the sampling frequency (i.e. fₛ/4), then the sampled values of the mixing signal can simply be 0, +1, 0, −1. This greatly simplifies multiplication for mixing since multiplication by −1, 0, +1 is trivial. 4 bit tunable capacitors adjust the center frequency of the modulator.

A single feed-forward path around the 2^{nd} resonator 22 further improves efficiency. The modulator 12 still retains the 2^{nd} order anti-alias filtering of the 1^{st} resonator 21. The feed-forward path reduces the signal swing at the output of the 2^{nd} resonator op-amp, relaxing power and linearity requirements. In addition, the feed-forward path removes a return-to-zero (RZ) feedback DAC to the 1^{st} resonator input, reducing the input-referred noise of the modulator. Overall, the modulator 12 has one RZ 28 and two half-clock-delayed return-to-zero 29 (HZ) current steering DACs.

The output currents from the two resonators are summed together, converted to voltages, and quantized by a 5-level 1040 MS/s flash quantizer 24. The low quantizer resolution facilitates MUX-based multiplication for down conversion and phase shifting. Programmable trim currents calibrate comparator offsets. A 3b tunable delay corrects any excessive loop delay, aligning the sampling at the quantizer and feedback current triggering.

In the example embodiment, the beamformer 10 contains eight continuous-time band-pass sigma delta modulators. Each modulator consumes 13.1 mW, and occupies only 0.03 mm², which is almost an order of magnitude smaller than conventional sigma delta modulators.

FIG. 3A provides an overview of the mathematical operations of digital down-conversion and phase shifting by complex weight multiplication. For each digital signal, a pair of down-mixers 31, 32 are used to generate an in-phase and quadrature (I/Q) output. The I/Q outputs of the down-mixers 31, 32 are weighted and combined to generate phase-shifted I/Q outputs. Additional mixers may be used to implement the weighting and combining functions. In this bit-stream processing approach, the digital outputs of the sigma delta modulators 12 are directly processed before they are low-pass filtered and decimated to enable MUX-based implementation of digital down-conversion and phase shifting.

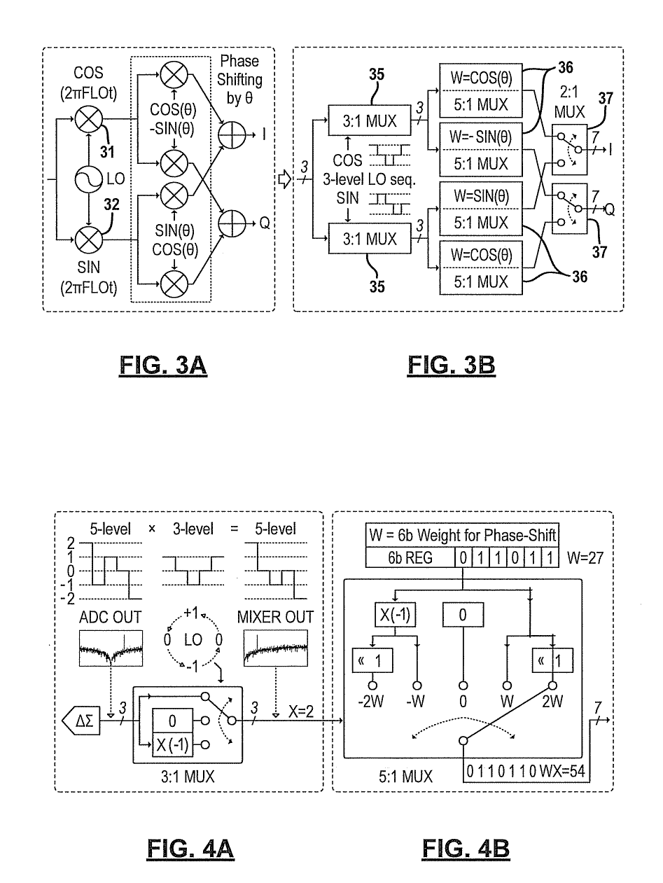

FIG. 3B depicts an example implementation of MUX-based digital down-conversion. In this example, an incoming signal is first down converted using a 3:1 multiplexer. More specifically, two 3:1 multiplexers 35 are used to generate I/Q outputs. Choosing a sigma delta modulator center frequency of fₛ/4 greatly simplifies the design of digital down-conversion, since the LO signals, cos [nπ/2] and sin [nπ/2], are represented by only three values (−1, 0, and +1). FIG. 4A further illustrates performing digital down-conversion with a simple 3:1 MUX: pass-through, zero, and sign-change. After multiplication by the 3-level LO signals (−1, 0, or +1), the down-mixed 5-level sigma delta modulator outputs are still represented by five levels (−2, −1, 0, +1, and +2).

With reference to FIG. 4B, complex weight multiplication can be implemented with a 5:1 multiplexer. Since all five levels of the down-converted signals are powers of 2, only 1b left-shift (<<1) and sign-change are required for multiplication. The 5-level output of the down-mixer determines the 5:1 MUX operation on the 6 bit stored weight (i.e. sign-change, zero, and 1 bit left-shift). In this way, a 5:1 MUX performs multiplication for phase shifting with 6 bit programmable weights. The result of this multiplication is a 7 bit output.

Returning to FIG. 3B, four 5:1 multiplexers 36 are used to implement complex weight multiplication for each digital signal received from a sigma delta modulator. In addition, since the 3-level I/Q LO sequences are alternately zeroes, only the in-phase component or the quadrature component of the down-mixer is non-zero at any time. Therefore, two 2:1 MUXes 37 can be used to implement the two adders as further seen in FIG. 3B. The four multipliers and two adders required for phase shifting are implemented with six multiplexers, greatly reducing circuit complexity.

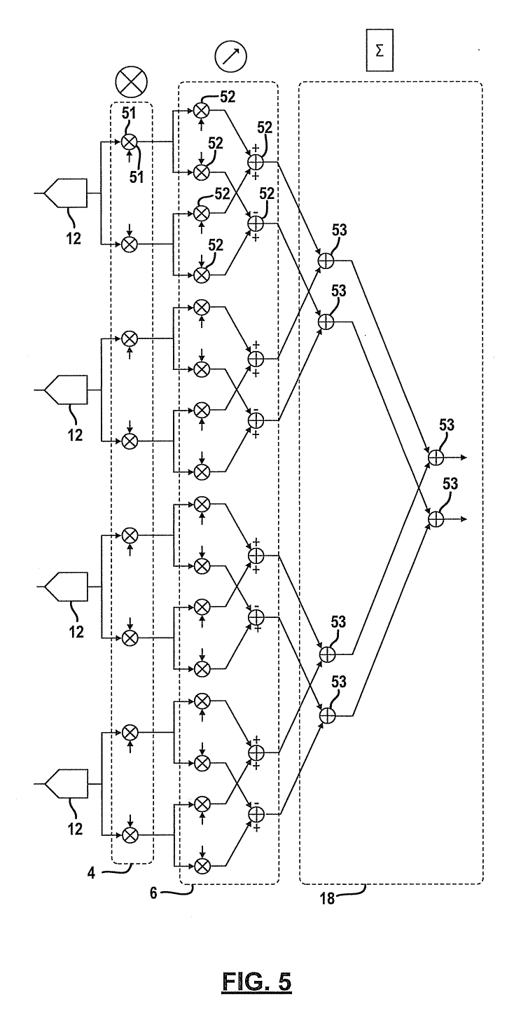

FIG. 5 further illustrates the implementation described above in the context digital beamformer 10. In this figure, only four of the eight sigma delta modulators 12 are shown. For each modulator 12, the arrangement of multipliers is shown. That is, for each modulator, two multipliers 51 are shown implementing down mixing and six multipliers 52 are shown for implementing phase shifting in the manner described above. Lastly, outputs from the phase shifter section 6 are input into summer 18. In this example, six additional additive mixers (i.e., summers) 53 are used to sum the signal to create the two resultant digital signals. It is readily understood that this arrangement for the summer can be scaled depending on the number signals received from the shifter section. Likewise, other arrangements for the summer also fall within the scope of this disclosure.

Beam forming combines the outputs of an array of antennas to form an effective beam directed in a particular direction. Beamforming replaces a mechanically steered antenna to achieve a beam that is electronically steered. For wireless communication, beam forming is helpful because it helps the receiver to ignore signals except those from the desired direction. Beam forming is valuable in radar because it allows the radar receiver consider RF signals from objects in a particular direction.

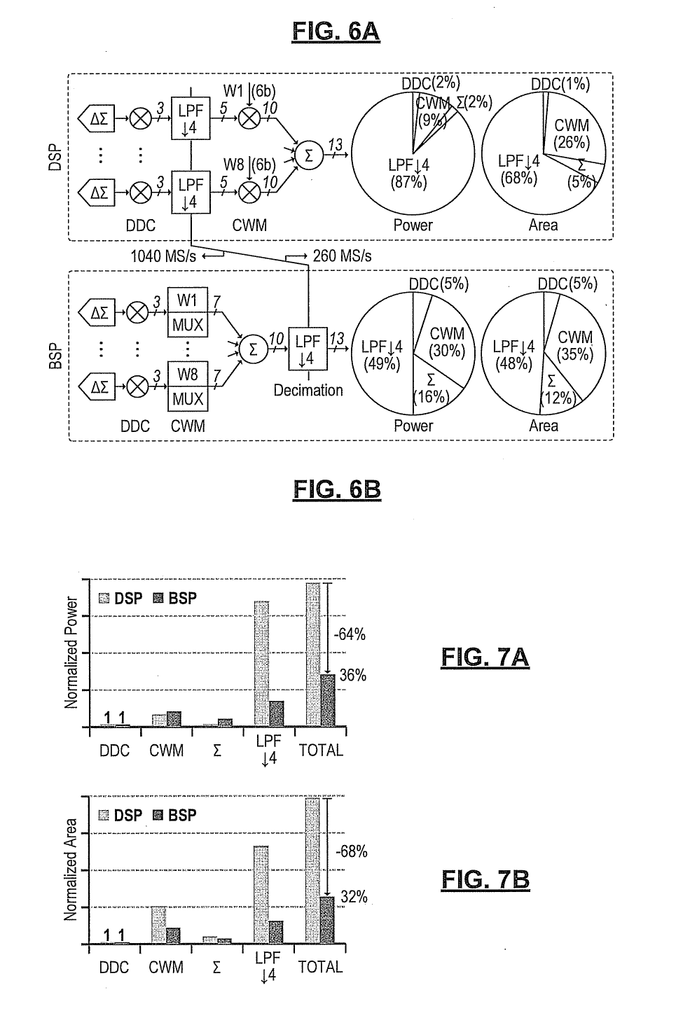

FIG. 6 compares the proposed bit-stream processing implementation of an 8-element digital beamformer with a conventional digital signal processing (DSP) implementation. The two implementations are compared in terms of power consumption and area based on the simulation of synthesized digital blocks.

In conventional DSP with over-sampling ADCs, the over-sampled digital ADC outputs are decimated before further signal processing so that back-end digital circuits can operate at lower data rates (but with increased word width), resulting in less power consumption. However, in a weighted-sum system (e.g. digital beamformer 10) with multiple inputs and a single output, the cost of decimation filtering increases linearly with the number of inputs, and therefore decimation filtering becomes a power and area bottleneck, as shown in FIG. 6.

In bit-stream processing, decimation filtering, a high-cost operation, is performed only once after all multiple paths are combined. This, however, requires complex weight multiplication for phase shifting to operate at higher data rates, but with lower word width. The penalty of higher data rate in bit-stream processing is overcome by replacing bulky multipliers with simple MUXes. As result, despite the higher data rate, MUX-based weighting achieves comparable power consumption to conventional multiplier-based weighting at a lower data rate, and greatly reduces area. As shown in FIGS. 7A and 7B, the power consumption and area of the proposed bit-stream processing implementation are 36% and 32%, respectively, of a conventional DSP implementation.

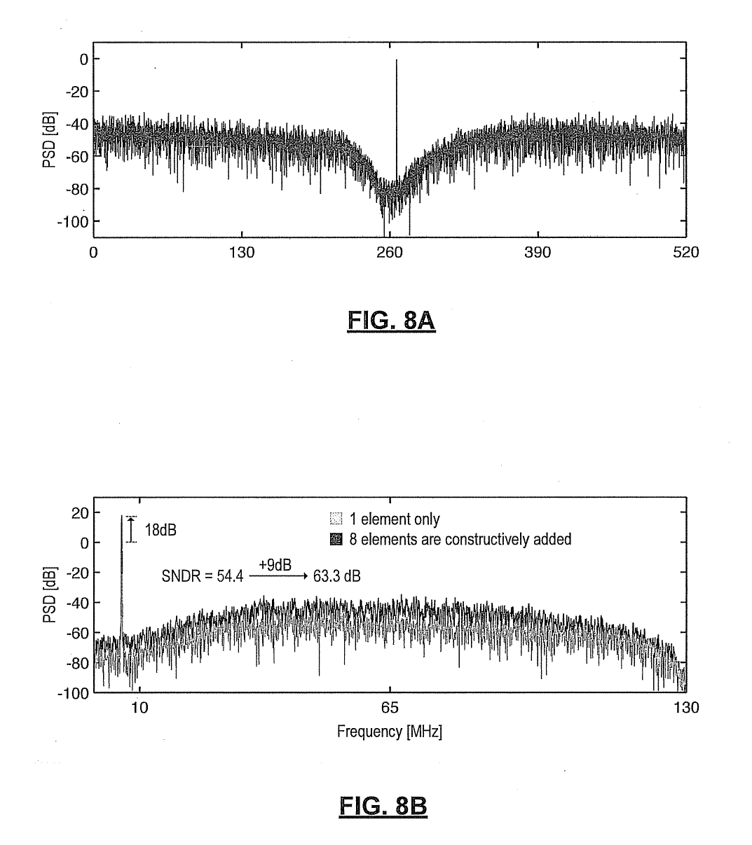

In an example implementation, an 8-element, 2-beam DBF IC is fabricated in 65 nm CMOS, and occupies a core area of 0.28 mm² (0.24 mm² for eight ADCs and 0.04 mm² for the DBF core). Each CTBPDSM consumes 13.1 mW from a 1.4V supply. For a single CTBPDSM with a 266 MHz input sinusoid, the average measured SNDR is 54.4 dB over a 20 MHz bandwidth as seen in FIG. 8A.

The outputs of the eight CTBPDSMs are fed to the Verilog synthesized DBF core, which consumes 18.9 mW from a 0.9V supply. When the eight CTBPDSM outputs are down-mixed, phase-shifted, and constructively added, the fundamental tone linearly increases by 18 dB while element noise is uncorrelated, resulting in an SNDR of 63.3 dB corresponding to a 9 dB array improvement over a 10 MHz bandwidth as seen in FIG. 8B.

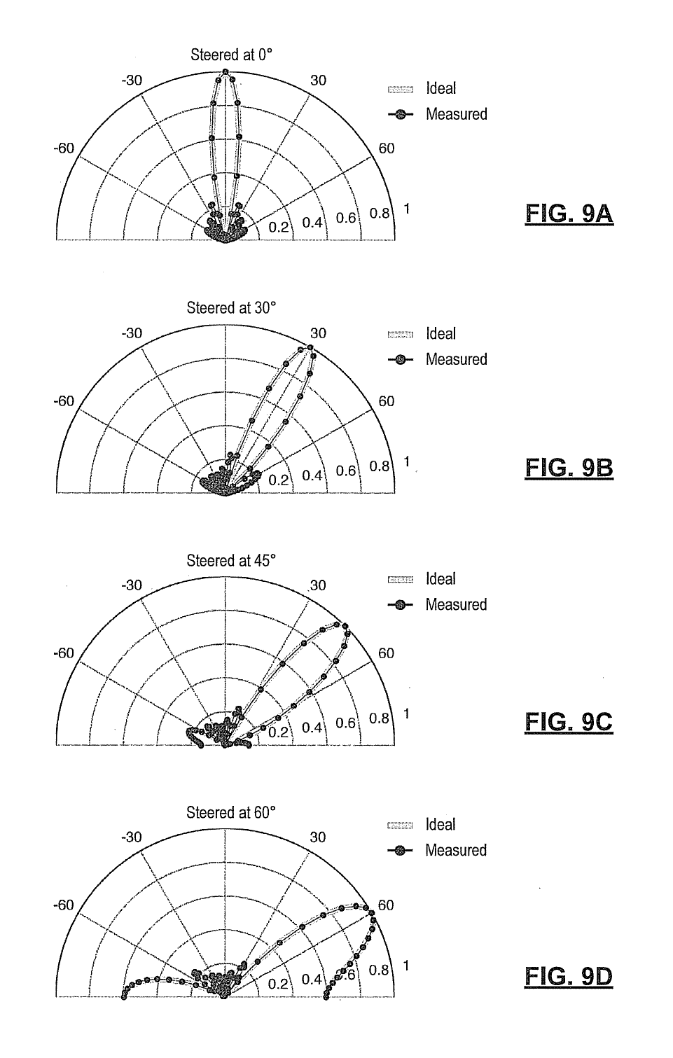

The prototype DBF IC produces two independent beams from eight input elements. Various weighting functions can be applied with 6b programmable weights. A simple phase-shift with a set of complex weights of e^{j(kθ)} (where k=0, 1, . . . , 7) adjusts the delay in the k-th channel to create one main-lobe at a desired angle. FIGS. 9A-9D show the measured single main-lobe beam patterns steered at different angles overlaid on ideal beam patterns. During measurements, eight synchronized direct digital synthesizers (DDSs) generate poly-phase sinusoidal inputs to mimic the received signals from an antenna array with λ/2 spacing. The beam measurement step size is 2.5°.

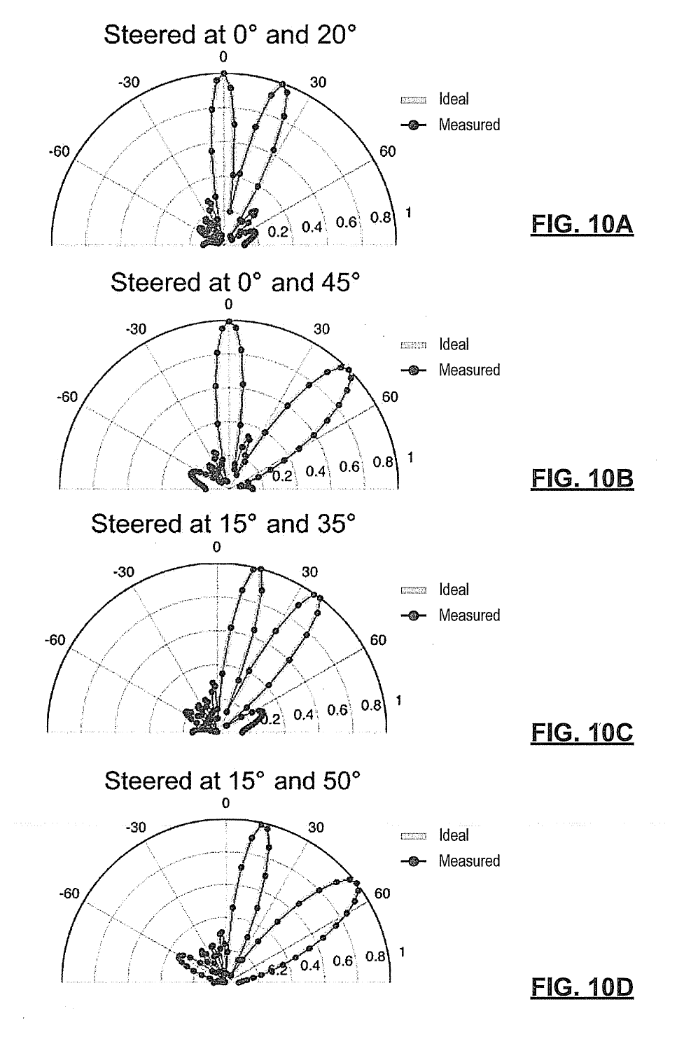

Also, combining two single main-lobe responses creates a single beam with two main-lobes. This is easily done in the digital domain by using combined complex weights of (e^{j(kθ}^{₁}⁾+e^{j(kθ}^{₂}⁾)/2 where k=0, 1, . . . , 7) at the cost of 6 dB reduced array gain. The measured beam patterns with two main-lobes are shown in FIGS. 10A-10D. A second simultaneous beam can be configured with the same flexibility. The measured beam patterns show great consistency with the ideal patterns, which is difficult to achieve in analog beamforming (ABF).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The apparatuses and methods described in this application may be partially or fully implemented in hardware, software or a combination thereof. The term hardware may refer to, be part of, or include: an Application Specific Integrated Circuit (ASIC); a digital, analog, or mixed analog/digital discrete circuit; a digital, analog, or mixed analog/digital integrated circuit; a combinational logic circuit; and a field programmable gate array (FPGA). The term software may include firmware, and/or microcode, and may refer to programs, routines, functions, classes, data structures, and/or objects. The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

1. A method for digital beamforming, comprising:
receiving, by an array of sigma delta modulators, a plurality of analog radio frequency (RF) signals from an RF front-end;
converting, by the array of sigma delta modulators, each of the analog RF signals into a corresponding digital signal using sigma-delta modulation;
bit-stream processing, by a bit stream processor, the digital signals received directly from the array of sigma delta modulators, the bit-stream processing includes down mixing each digital signal using a first multiplication operation and phase shifting each multiplied digital signal by weighting the respective multiplied digital signal using a second multiplication operation; and
summing, by the bit stream processor, each of the bit-stream processed digital signals to form a resultant signal.

2. The method of claim 1 wherein each sigma delta modulator in the array of sigma delta modulators is further defined as a continuous-time band-pass sigma delta modulator.

3. The method of claim 1 further comprises down mixing each digital signal at one quarter sampling rate of the sigma delta modulators.

4. The method of claim 1 wherein down mixing further comprises multiplying each digital signal by a multiplier, the multiplier being selected from a group of three or more values.

5. The method of claim 4 wherein phase shifting further comprises multiplying each digital signal by a multiplier, the multiplier being selected from a group of five or more values.

6. The method of claim 5 wherein phase shifting includes multiplying a value of a given digital signal by two by left shifting the value of the given digital signal.

7. The method of claim 6 further comprises multiplying each digital signal by a multiplier using a multiplexer and phase shifting each multiplied signal using a multiplexer.

8. The method of claim 7 further comprises decimating the resultant signal using a filter.

9. A method for digital beamforming, comprising:
receiving, by an array of sigma delta modulators, a plurality of intermediate frequency (IF) analog signals from an RF front-end;
converting, by the array of sigma delta modulators, each of the IF analog signals into a corresponding digital signal using sigma-delta modulation;
down mixing, by a first set of multiplexers, each digital signal by multiplying the respective digital signal by a multiplier, where the multiplier is selected from a group of one, zero or minus one;
weighting, by a second set of multiplexers, each down mixed digital signal with a weight, where the weight is selected from a group of two, one, zero, minus one or minus two; and
summing, by a bit stream processor, each of the weighted digital signals together to form a resultant digital signal.

10. The method of claim 9 wherein each sigma delta modulator in the array of sigma delta modulators is further defined as a continuous-time band-pass sigma delta modulator.

11. The method of claim 10 wherein values output by each sigma delta modulator in the array of sigma delta modulators is represented by five signal levels.

12. The method of claim 11 further comprises down mixing each digital signal to generate a corresponding in-phase signal and a corresponding quadrature signal.

13. The method of claim 12 further comprises weighting the in-phase signal and the quadrature signal with a weight and selecting one of the weighted in-phase signal and the weighted quadrature signal using a multiplexer.

14. The method of claim 12 wherein weighting each down mixed signals includes multiplying by two by left shifting the values of a given down mixed digital signal.

15. The method of claim 10 further comprises down mixing each digital signal at one quarter of sampling rate of the sigma delta modulators.

16. The method of claim 10 further comprises decimating the resultant signal using a filter.

17. A digital beamformer, comprising:
an array of sigma delta modulators, each sigma delta modulator configured to receive an intermediate frequency (IF) analog signal and operates to convert the IF analog signal to a corresponding digital signal;
a first set of multiplexers configured to receive the digital signals from the array of sigma delta modulators, each multiplexer in the first set of multiplexers operates to down mix one of the digital signals using a multiplication operation;
a second set of multiplexers configured to receive the down mixed digital signals from the first set of multiplexers and operates to phase shift each down mixed digital signal using a multiplication operations;
a set of additive mixers configured to receive the phase shifted digital signals from the second set of multiplexers and operates to add the phase shifted signals together to form a resultant digital signal.

18. The digital beamformer of claim 17 wherein each sigma delta modulator in the array of sigma delta modulators is further defined as a continuous-time band-pass sigma delta modulator.

19. The digital beamformer of claim 17 wherein, for each digital signal received from the array of sigma delta modulators, the first set of multiplexers includes one multiplexer that outputs an in-phase signal components for a given digital signal and another multiplexer that outputs a quadrature signal component for the given digital signal.

20. The digital beamformer of claim 17 further comprises one or more decimator filters, where the number of decimator filters equals the number of resultant signals.
